(19) United States
(12) Patent Application Publication
(10) Pub. No.: US 2008/0083958 A1
(43) Pub. Date: Apr. 10, 2008

(54) MICRO-ELECTROMECHANICAL SYSTEM PACKAGE

(76) Inventors: Wen-Chieh Wei, Taichung Industrial Park (TW); Hong-Ching Her, Taichung (TW); Shih-Chin Gong, Taipei (TW); Chih-Wei Chang, Taichung Hsien (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/620,156

(22) Filed: Jan. 5, 2007

Related U.S. Application Data
(63) Continuation-in-part of application No. 11/539,025, filed on Oct. 5, 2006.

(51) Int. Cl. H01L 29/84

(52) U.S. Cl. 257/415; 257/678

(57) ABSTRACT

A micro-electromechanical system package includes a substrate, a set of components, at least one solder pad, a frame, a peripheral shield and a top shield. The set is provided on the substrate. At least one solder pad is attached to the substrate opposite to the set. A frame is provided on the substrate. A peripheral shield is provided on the substrate around the set. The isolative stuff seals the set. The isolative stuff defines a tunnel. The top shield is provided on the isolative stuff for shielding the set from electromagnetic interference. The top shield includes a column inserted through the tunnel and connected to the solder pad.

### CROSS-REFERENCE

The present patent application is a continuation-in-part application of U.S. patent application Ser. No. 11/539,025 filed on Oct. 5, 2006.

### BACKGROUND OF INVENTION

1. Field of Invention

The present invention relates to a micro-electromechanical system (“MEMS”) package and, more particularly, to a MEMS package that is shielded from moisture and electromagnetic interference.

2. Related Prior Art

Disclosed in U.S. Pat. No. 6,781,231 is a conventional MEMS package 10 including a substrate 14, a plurality of components 12 installed on the substrate 14 and a cover 20 installed on the substrate 14 for covering the components 12. The cover 20 consists of an external cup 25a and an internal cup 25b disposed in the external cup 25a. The cover 20 is used as a shield against electro-magnetic interference. The cover 20 and the substrate 14 define a housing 22. The cover 20 includes a plurality of acoustic ports 44 each including an environmental barrier layer 48.

Problems have been encountered in the use of the MEMS package 10. Firstly, the housing 22 contains air that inevitably includes moisture. When micromechanical system package 10 is moved from a cool area to a warm area such as from an air-conditioned room to the outside, the components 12 and the cover 20 remain cool so that the moisture condenses on the components 12 and/or the cover 20. The components 12 and/or the cover 20 may be damaged because of the moisture.

Secondly, the housing 22, which is a cap-shaped metal element, keeps the moisture therein, and the moisture jeopardizes the isolation of the components 12 from the cover 20 and the isolation of the components 12 from one another. Therefore, the performance of the MEMS package 10 is affected.

Thirdly, the micro-electromechanical system package 10 is bulky for including the cover 20.

Fourthly, the packaging process by using the cover 20 is different from the typical packaging processes for semiconductors.

The present invention is therefore intended to obviate or at least alleviate the problems encountered in prior art.

### SUMMARY OF INVENTION

A micro-electromechanical system package includes a substrate, a set of components, at least one solder pad, a frame, a peripheral shield and a top shield. The set is provided on the substrate. At least one solder pad is attached to the substrate opposite to the set. A frame is provided on the substrate. The peripheral shield is provided on the substrate around the set for shielding the set from electromagnetic interference. The isolative stuff seals the set. The isolative stuff defines a tunnel. The top shield is provided on the isolative stuff for shielding the set from electromagnetic interference. The top shield includes a column inserted through the tunnel and connected to the solder pad.

An advantage of the micro-electromechanical system package according to the present invention is sealing the set.

Another advantage of the micro-electromechanical system package according to the present invention is shielding the set from electromagnetic interference.

Other advantages and features of the present invention will become apparent from the following description referring to the drawings.

### BRIEF DESCRIPTION OF DRAWINGS

The present invention will be described via detailed illustration of four embodiments referring to the drawings.

FIG. 1 is a cross-sectional view of an MEMS package according to the first embodiment of the present invention.

FIG. 2 is a top view of the MEMS package shown in FIG. 1.

FIG. 3 is a cross-sectional view of a series of MEMS packages such as shown in FIG. 1.

FIG. 4 is a cross-sectional view of an MEMS package according to the second embodiment of the present invention.

FIG. 5 is a cross-sectional view of a series of MEMS packages such as shown in FIG. 4.

FIG. 6 is a cross-sectional view of an MEMS package according to the third embodiment of the present invention.

FIG. 7 is a top view of the MEMS package shown in FIG. 6.

FIG. 8 is a cross-sectional view of an MEMS package according to the fourth embodiment of the present invention.

### DETAILED DESCRIPTION OF EMBODIMENTS

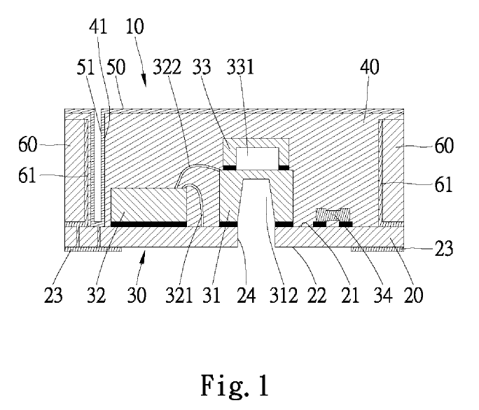

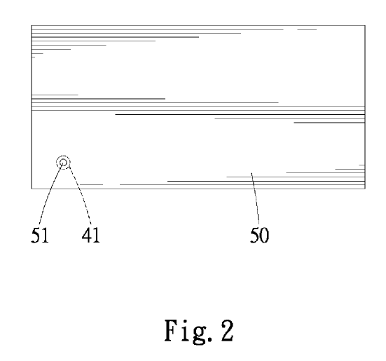

Referring to FIGS. 1 and 2, according to a first embodiment of the present invention, a MEMS package 10 includes a substrate 20, a set 30 of components, a frame 60, a peripheral shield 61, isolative stuff 40 and a top shield 50.

The substrate 20 is made with an upper face 21 and a lower face 22. The set 30, the isolative stuff 40, the frame 60, the peripheral shield 61 and the top shield 50 are attached to the upper face 21 of the substrate 20. A plurality of solder pads 23 is formed on the lower face 22 of the substrate 20. Via the solder pads 23, the substrate 20 is electrically connected to a circuit board of an electronic device that incorporates the MEMS package 10. The substrate 20 defines a sound aperture 24 through which sound waves travel.

The set 30 includes a plurality of components for executing the functions of the MEMS package 10. Preferably, the set 30 includes a MEMS microphone 31, an application specific integrated circuit (“ASIC”) 32 and a passive element 34. The MEMS microphone 31 is provided on the upper face 21 of the substrate 20. The MEMS microphone 30 defines a chamber 312. The chamber 312 is in communication with the sound aperture 24. Sound waves can reach and cause the MEMS microphone 30 to vibrate.

A cover 33 is provided on the MEMS microphone 31 so that a chamber 331 is defined by the cover 33 and the MEMS microphone 31. The chamber 331 allows the vibration produced by the MEMS microphone 31.

The ASIC 32 is provided on the upper face 21 of the substrate 20. The ASIC 32 is electrically connected to the substrate 20 by a wire 321 on one hand and electrically connected to the MEMS microphone 31 by a wire 322 on the other hand.

The passive element 34 is provided on the upper face 21 of the substrate 20. The passive element 34 may be a capacitor, resistor or inductor.

In use, on receiving the sound waves, the MEMS microphone 31 generates the changes in the capacitance. On receiving the changes in the capacitance, the ASIC 32 produces electric signals corresponding to the changes in the capacitance. The electric signals are passed through the passive element 34 while the fundamental characteristics thereof are not changed.

The isolative stuff 40 is provided on the set 30 and the upper face 21 of the substrate 20, thus completely sealing the set 30. In specific, all of the MEMS microphone 31, the ASIC 32 and the passive element 34 are sealed by the isolative stuff 40. The set 30 is kept from moisture that would otherwise damage the set 30. A tunnel 41 is defined in the isolative stuff 40.

The isolative stuff 40 is molded of a molding compound such as molding gel. During the molding, an insert is used for making the tunnel 41 in the isolative stuff 40. The dimensions, such as the thickness and area, of the isolative stuff 40 are determined according to the desired dimensions of the MEMS package 10.

The peripheral shield 61 is a coating of metal on an internal side and the bottom of the frame 60. The peripheral shield 61 is preferably provided by sputtering. The peripheral shield 61 is connected to one of the solder pads 23. The peripheral shield 61 shields the set 30 from electromagnetic interference.

The top shield 50 is a coating of metal on the isolative stuff 40. The top shield 50 is connected to one of the solder pads 23 by a column 51. The top shield 50 shields the set 30 from electromagnetic interference. The top shield 50 and the column 51 are preferably provided by sputtering.

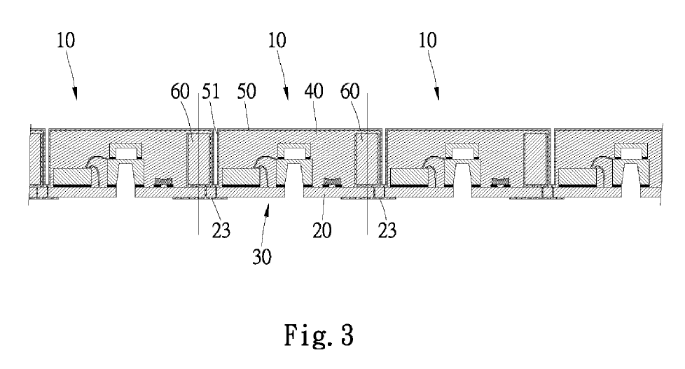

Referring to FIG. 3, there are MEMS packages 10 in an array-type packaging process typically for making semiconductors. Many substrates 20 are made as one in the form of a plate. A corresponding number of sets 30 are provided on the plate. Bonding is conducted. A corresponding number of frames 60 are made as one in the form of a grid. A corresponding number of peripheral shields 61 are made as one in the form of a first coating on the grid. The grid and the first coating are located on the plate. The isolative stuff 40 is provided on the grid, the first coating, the sets 30 and the plate. A corresponding number of top shields 50 are made as one in the form of a second coating on the isolative stuff 40 and the substrate 20. Finally, the MEMS packages 10 are cut from one another.

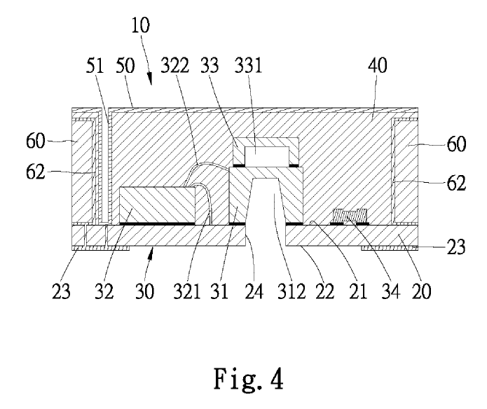

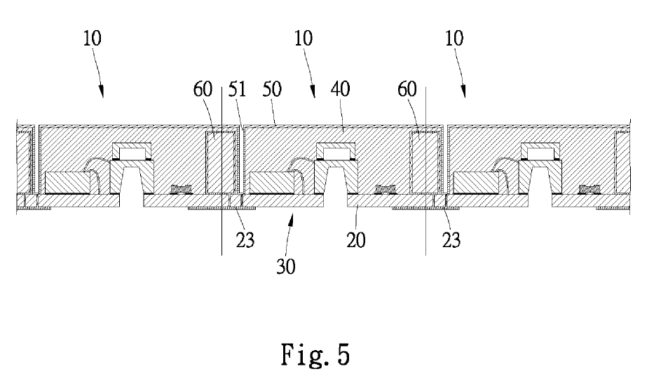

Referring to FIGS. 4 and 5, there is shown a MEMS package 10 according to a second embodiment of the present invention. The second embodiment is like the first embodiment except using a peripheral shield 62 instead of the peripheral shield 61. The peripheral shield 62 covers the top of the frame 60 as well as the bottom and the side.

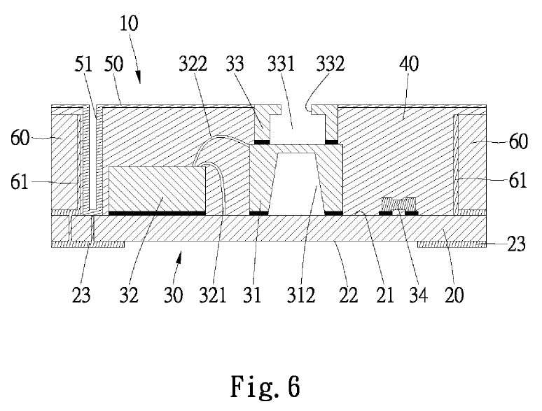

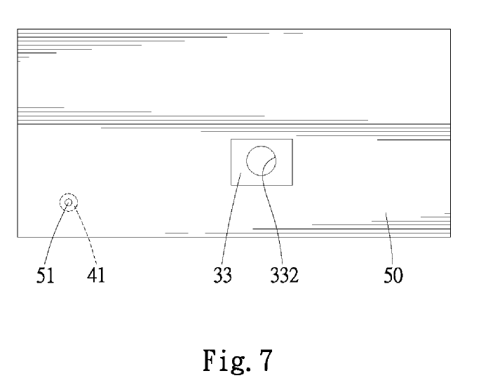

Referring to FIGS. 6 and 7, there is shown a MEMS package 10 according to a third embodiment of the present invention. The third embodiment is like the first embodiment except defining a sound aperture 332 in the cover 33 instead of the sound aperture 24 in the substrate 20. Preferably, the isolative stuff 40 and the top shield 50 do not cover the top of the cover 33 so that the top of the cover 33 is located higher than the top of the frame 60. However, the isolative stuff 40 and/or the top shield 50 may cover the top of the cover 33 except the sound aperture 332. The sound aperture 332 is in communication with the chamber 331. Therefore, sound waves reach the MEMS microphone 31 through the chamber 331 and the sound aperture 332. On receiving the sound waves, the MEMS microphone 31 vibrates and changes the capacitance thereof. The chamber 312 allows the vibration of the MEMS microphone 31.

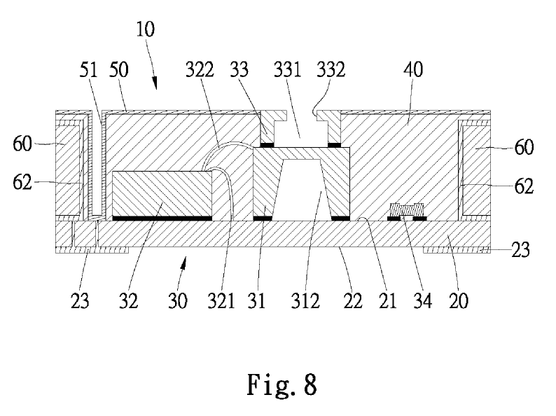

Referring to FIG. 8, there is shown a MEMS package 10 according to a fourth embodiment of the present invention. The fourth embodiment is like the third embodiment except using a peripheral shield 62 instead of the peripheral shield 61. The peripheral shield 62 covers the top of the frame 60 as well as the bottom and the side.

The MEMS package 10 according to the present invention exhibits several advantages. Firstly, by the isolative stuff, the components are kept from moisture that would otherwise be entailed by change in temperature.

Secondly, it can be made as small as possible since the dimensions of the isolative stuff are controlled according to various needs.

Thirdly, the components are shielded from electromagnetic interference by the top shield provided on the isolative stuff and connected to the electronic device that incorporates the MEMS package.

The present invention has been described via the detailed illustration of the embodiments. Those skilled in the art can derive variations from the embodiments without departing from the scope of the present invention. Therefore, the embodiments shall not limit the scope of the present invention defined in the claims.

What is claimed is:

1. A micro-electromechanical system package comprising:
a substrate;
a set of components provided on the substrate;
at least one solder pad attached to the substrate opposite to the set;
a frame provided on the substrate;
a peripheral shield provided on the substrate around the set;
isolative stuff for sealing the set, the isolative stuff defining a tunnel; and
a top shield provided on the isolative stuff for shielding the set from electromagnetic interference, the top shield comprising a column inserted through the tunnel and connected to the solder pad.

2. The micro-electromechanical system according to claim 1 wherein the peripheral shield covers the bottom and a side of the frame.

3. The micro-electromechanical system according to claim 1 wherein the peripheral shield covers the top, the bottom and a side of the frame.

4. The micro-electromechanical system according to claim 1 wherein the set comprises a micro-electromechanical system microphone and an application specific integrated circuit electrically connected to the micro-electromechanical system microphone.

5. The micro-electromechanical system according to claim 4 wherein the micro-electromechanical system microphone defines a lower chamber below the membrane and an upper chamber above the membrane so that the lower and upper chambers allow the vibration of the membrane.

6. The micro-electromechanical system package according to claim 5 wherein the substrate defines a sound aperture in communication with the lower chamber so that sound waves travel to the membrane through the lower chamber and the sound aperture.

7. The micro-electromechanical system according to claim 5 comprising a cover provided on the micro-electromechanical system microphone so that the upper chamber is defined by the cover and the micro-electromechanical system microphone.

8. The micro-electromechanical system package according to claim 7 wherein the cover, the isolative shield and the top shield define a sound aperture in communication with the upper chamber so that sound waves travel to the membrane through the upper chamber and the sound aperture.

9. The micro-electromechanical system package according to claim 1 wherein the peripheral shield is provided by sputtering.

10. The micro-electromechanical system package according to claim 1 wherein the top shield is provided by sputtering.

11. The micro-electromechanical system package according to claim 1 wherein the isolative stuff is made of a molding compound.
